(19) United States
(12) Patent Application Publication
(10) Pub. No.: US 2016/0126375 A1
(43) Pub. Date: May 5, 2016

(54) SOLAR CELL, METHOD FOR MANUFACTURING THE SAME, AND SOLAR CELL MODULE

(71) Applicant: MITSUBISHI ELECTRIC CORPORATION, Chiyoda-ku, Tokyo (JP)

(72) Inventor: Hiroaki MORIKAWA, Tokyo (JP)

(73) Assignee: Mitsubishi Electric Corporation, Chiyoda-ku, Tokyo (JP)

(21) Appl. No.: 14/893,776

(22) PCT Filed: May 28, 2013
(86) PCT No.: PCT/JP2013/064803

§ 371 Date: Nov. 24, 2015

(51) Int. Cl. H01L 31/0224; H01L 31/05; H01L 31/068; H01L 31/18; H01L 31/0216; H01L 31/02

(52) U.S. Cl. CPC H01L 31/022433; H01L 31/02168; H01L 31/0201; H01L 31/068; H01L 31/1804; H01L 31/0508

(57) ABSTRACT

A solar cell includes: a first-conductivity-type semiconductor substrate including an impurity diffusion layer, in which a second-conductivity-type impurity element is diffused, on one surface side; a light-receiving surface-side electrode including a grid electrode and a bus electrode having a wider width than the grid electrode and in electrical communication with the grid electrode, and formed on the one surface side and electrically connected to the impurity diffusion layer; and a rear surface side electrode formed on a rear surface and electrically connected to the impurity diffusion layer, wherein the light-receiving surface-side electrode includes a first metal electrode layer directly bonded to the one surface side, and a second metal electrode layer that is formed of a metal material different from the first metal electrode layer and having electrical resistivity substantially equivalent to the first metal electrode layer and is formed to cover the first metal electrode layer.

### FIELD

The present invention relates to a solar cell, a method for manufacturing the same, and a solar cell module.

### BACKGROUND

The mainstream electric-power solar cell currently used worldwide is a bulk-type silicon solar cell using a silicon substrate. Various researches have been conducted into the process flow of the mass production of silicon solar cells in order to reduce the manufacturing cost thereof by simplifying the process as much as possible.

Conventional bulk-type silicon solar cells (hereinafter, sometimes also referred to as “solar cells”) have been generally manufactured according to the following method. First, for example, a p-type silicon substrate is prepared as a first-conductivity-type substrate. In the silicon substrate, a damaged layer on the silicon surface generated when the silicon substrate is sliced from a cast ingot is then removed by a thickness of 10 micrometers to 20 micrometers by an alkaline solution, such as a solution that is several to 20 percent by weight sodium hydroxide or potassium hydroxide.

A surface relief structure referred to as “texture” is produced on the surface from which the damaged layer has been removed. On the front surface side (the light-receiving surface side) of the solar cell, such a texture is generally formed in order to take in as much sunlight as possible onto the p-type silicon substrate by suppressing light reflection. One production method of the texture, for example, is a method referred to as the “alkali texture method”. According to the alkali texture method, in order to form a texture such that a silicon (111) surface is exposed, anisotropic etching is performed in a solution in which an additive that promotes anisotropic etching such as IPA (isopropyl alcohol) is added to a low-concentration alkaline solution such as a solution that is several percent by weight sodium hydroxide or potassium hydroxide.

Subsequently, in a diffusion process, the p-type silicon substrate is treated, for example, in a mixed gas atmosphere of phosphorous oxychloride (POCl₃), nitrogen, and oxygen at a temperature of 800° C. to 900° C. for several tens of minutes, to form an n-type impurity diffusion layer as a second-conductivity-type impurity layer uniformly over the entire surface. When there is no particular variation, the n-type impurity diffusion layer is formed over the entire surface of the p-type silicon substrate. The sheet resistance of the n-type impurity diffusion layer formed uniformly on the silicon surface is about several tens of Ω/□, and the depth of the n-type impurity diffusion layer is about 0.3 micrometers to 0.5 micrometers.

Because the n-type impurity diffusion layer is uniformly formed on the silicon surface, the front surface and the rear surface of the silicon substrate are electrically connected. To interrupt electric connection therebetween, the end face area of the p-type silicon substrate is etched by, for example, dry etching. As another method, end face separation of the p-type silicon substrate may be performed by laser. Thereafter, the p-type silicon substrate is immersed in a hydrofluoric acid aqueous solution to remove by etching a glassy material (PSG) deposited on the surface during the diffusion process.

Subsequently, an insulating film, such as a silicon oxide film, a silicon nitride film, a titanium oxide film, is formed with a uniform thickness on the surface of the n-type impurity diffusion layer as an insulating film (an anti-reflective film) for preventing reflection. When a silicon nitride film is formed as the anti-reflective film, the silicon nitride film is formed by using silane (SiH₄) gas and ammonia (NH₃) gas as raw materials, for example, by a plasma CVD method at a temperature of 300° C. or higher under reduced pressure. The refractive index of the anti-reflective film is about 2.0 to 2.2, and the optimum film thickness is about 70 nanometers to 90 nanometers. Note that the anti-reflective film formed in this manner is an insulating body, and it does not work as a solar cell merely by simply forming the light-receiving surface-side electrode thereon.

A silver paste, which becomes the light-receiving surface-side electrode, is applied to the anti-reflective film by a screen printing method in the shape of a grid electrode and a bus electrode and is then dried. The silver paste for the light-receiving surface-side electrode is formed on the insulating film to prevent reflection.

A rear aluminum electrode paste, which becomes a rear aluminum electrode, and a rear silver paste, which becomes a rear silver bus electrode, are applied to the rear surface of the substrate by the screen printing method in the shapes of the rear aluminum electrode and the rear silver bus electrode, respectively, and are then dried.

The electrode pastes applied to the front surface and rear surface of the silicon substrate are simultaneously fired according to a firing profile for several minutes to ten and several minutes during which the peak temperature for several seconds becomes 700° C. to 900° C. Accordingly, a grid electrode and a bus electrode are formed as the light-receiving surface-side electrodes on the front surface side of the silicon substrate, and a rear aluminum electrode and a rear silver bus electrode are formed as the rear surface side electrodes on the rear surface side of the silicon substrate. The silver material comes into contact with silicon and is coagulated again, while the anti-reflective film is melted by the glass material contained in the silver paste on the light-receiving surface side of the silicon substrate. Accordingly, conduction between the light-receiving surface-side electrode and the silicon substrate (the n-type impurity diffusion layer) is ensured. Such a process is referred to as “fire through method”. A thick film paste composition obtained by dispersing metallic powder as a main component and glass powder in an organic vehicle is used as the metal paste used as the electrode. Glass powder contained in the metal paste reacts with a silicon surface and is firmly fixed thereto, thereby maintaining the mechanical strength of the electrode.

Aluminum is also diffused as an impurity from the rear aluminum electrode paste to the rear surface side of the silicon substrate during firing, and a p+ layer (BSF (Back Surface Field)) containing aluminum as the impurity at a higher concentration than the silicon substrate is formed immediately beneath the rear aluminum electrode. By performing such processes, a bulk-type silicon solar cell is formed.

As an approach to cost reduction of such solar cells, conventionally, efforts to reduce the cost of the constituent materials of the solar cell have been continuously made. The most expensive constituent material among the constituent materials of the solar cell is the silicon substrate. Therefore, there have been continuous efforts to reduce the thickness of the silicon substrate. The thickness of the silicon substrate was mainly about 350 micrometers when the mass production of solar cells first began. However, currently, silicon substrates having thicknesses of about 160 micrometers are produced.

The intention to achieve cost reduction is extended to all the materials constituting the solar cell. The next most expensive material after the silicon substrate among the constituent materials of the solar cell is the silver (Ag) electrode, and studies on an alternative to the silver (Ag) electrode have been started.

For example, in Non Patent Literature 1, there is a description that a portion where a comb-like electrode formed in a silicon nitride film that is used as an anti-reflective film is removed by laser to provide an opening, and then the opening is plated with nickel (Ni), copper (Cu), and silver (Ag) in the order that they appear in this sentence. That is, Non Patent Literature 1 discloses the possibility of using copper (Cu) as an alternative to silver (Ag).

Meanwhile, in Non Patent Literature 2, there is a description that after forming a silver (Ag) paste electrode by the conventional screen printing, silver (Ag) plating is performed again. It is disclosed that plating is effective as a method of forming the electrode.

A method has been proposed of achieving cost reduction by sequentially plating an Ag paste electrode that is printed by screen printing and is fired with nickel (Ni), copper (Cu), and tin (Sn) in the order that they appear in this sentence, instead of plating with silver (Ag) as described in Non Patent Literature 2. For example, Meco Equipment Engineers B.V., an affiliate company of BE Semiconductor Industries N.V. (Besi), has started selling of the equipment for the above process (see, for example, Non Patent Literature 3).

### CITATION LIST

### Non Patent Literatures

Non Patent Literature 1: L. Tous, et al. “Large area copper plated silicon solar cell exceeding 19.5% efficiency”, 3rd Workshop on Metallization for Crystalline Silicon Solar cells 25-26 Oct. 2011, Chaleroi, Belgium

Non Patent Literature 2: E. Wefringhaus, et al. “ELECTROLESS SILVER PLATING OF SCREEN PRINTED GRIFD FINGERS AS A TOOL FOR ENHANCEMENT OF SOLAR EFFICIENCY”, 22nd European Photovoltaic Solar Energy Conference, 3-7 Sep. 2007, Milan, Italy

Non Patent Literature 3: [searched on Apr. 4, 2013], Internet <URL:http://www.besi.com/products-and-technology/plating/solar-plating-equipment/meco-cpl-more-power-out-of-your-cell-at-a-lower-cost-38>

### SUMMARY

### Technical Problem

However, in the case of Non Patent Literature 1, reproducibility and uniformity of processing when removing the silicon nitride film by laser can be mentioned as a problem. During the processing of a silicon nitride film by laser, if the laser power is high, it is assumed that the n-type impurity diffusion layer may be thermally damaged, and if the laser power is low, it is assumed that processing of the silicon nitride film may not be performed sufficiently.

In the case of Non Patent Literature 1, in addition to the problem with the industrial stability of laser processing as described above, there are problems such as variations in the thickness of a wafer, irregularities in the silicon structure on a texture surface, and mechanical variations when scanning the comb-like shape by laser. Therefore, the method described in Non Patent Literature 1 has not been widely used. Further, moisture resistance and temperature-resistant cycle properties are required for the solar cell to be reliable. However, the electrode structure formed according to the method described in Non Patent Literature 1 cannot be said to be a structure whose reliability has been sufficiently verified when consideration is given with electrodes available in the market.

Meanwhile, Non Patent Literature 2 attempts to realize thinning more than the conventional electrode structure formed only by screen printing by, after thinning an Ag electrode by conventional screen printing, further developing the Ag electrode by plating, i.e., by utilizing plating. Further, in Non Patent Literature 2, there is a description of an attempt to suppress the electrode width after plating to less than 100 micrometers by setting the electrode width before plating to 60 micrometers to 85 micrometers. Because the width of the electrode formed only by the conventional screen printing is 120 micrometers, thinning of the electrode is achieved and photoelectric conversion efficiency is improved. However, with the electrode width of about 100 micrometers, thinning of the electrode is not sufficient in view of achieving still higher photoelectric conversion efficiency.

In Non Patent Literature 3, because the width of an Ag past electrode formed initially by screen printing becomes at least about 50 micrometers or more, the electrode width after plating becomes about less than 100 micrometers. However, with the electrode width of about 100 micrometers, thinning of the electrode is not sufficient in view of achieving still higher photoelectric conversion efficiency.

As described above, many variations have been contrived regarding the formation method of a light-receiving surface-side electrode so as to realize high photoelectric conversion efficiency and cost reduction of the solar cells. That is, by using a plating technique, use of alternative materials and efforts to achieve high photoelectric conversion efficiency (thinning) have been made. However, as described above, the method described in Non Patent Literature 1 aiming at achieving cost reduction has problems with reproducibility and reliability in production. The methods described in Non Patent Literatures 2 and 3 aiming at achieving high photoelectric conversion efficiency are an extension of the conventional screen printing and thinning is still not sufficient.

The present invention has been achieved in view of the above problems, and an object of the present invention is to provide a solar cell excellent in achieving cost reduction and high photoelectric conversion efficiency, a method for manufacturing the same, and a solar cell module.

### Solution to Problem

In order to solve the above problems and achieve the object, a solar cell according to an aspect of the present invention is a solar cell including: a first-conductivity-type semiconductor substrate that includes an impurity diffusion layer, in which a second-conductivity-type impurity element is diffused, on one surface side, which is a light-receiving surface side; a light-receiving surface-side electrode that includes a grid electrode and a bus electrode having a wider width than the grid electrode and in electrical communication with the grid electrode, and that is formed on the one surface side so as to be electrically connected to the impurity diffusion layer; and a rear surface side electrode that is formed on a rear surface opposite to the one surface side of the semiconductor substrate so as to be electrically connected to the impurity diffusion layer, wherein the light-receiving surface-side electrode includes a first metal electrode layer that is a metal paste electrode layer directly bonded to the one surface side of the semiconductor substrate, and a second metal electrode layer that is a plating electrode layer that is formed of a metal material different from the first metal electrode layer and having an electrical resistivity substantially equivalent to an electrical resistivity of the first metal electrode layer and that is formed to cover the first metal electrode layer, and a sectional area of the grid electrode is 300 μm² or more, and an electrode width of the grid electrode is 60 micrometers or less.

### Advantageous Effects of Invention

According to the present invention, an effect is obtained where a solar cell excellent in achieving cost reduction and high photoelectric conversion efficiency can be obtained.

### BRIEF DESCRIPTION OF DRAWINGS

FIG. 1-1 is an explanatory diagram of a configuration of a solar cell according to a first embodiment of the present invention and is a top view of the solar cell as viewed from a light-receiving surface side.

FIG. 1-2 is an explanatory diagram of the configuration of the solar cell according to the first embodiment of the present invention and is a bottom view of the solar cell as viewed from an opposite side (a rear surface side) to a light-receiving surface.

FIG. 1-3 is an explanatory diagram of the configuration of the solar cell according to the first embodiment of the present invention and is a sectional view of relevant parts of the solar cell.

FIG. 1-4 is an explanatory diagram of the configuration of the solar cell according to the first embodiment of the present invention and is a sectional view of relevant parts illustrating the vicinity of a surface silver grid electrode of a light-receiving surface-side electrode in FIG. 1-3 in an enlarged manner.

FIG. 2-1 is an explanatory sectional view of a manufacturing process of the solar cell according to the first embodiment of the present invention.

FIG. 2-2 is an explanatory sectional view of the manufacturing process of the solar cell according to the first embodiment of the present invention.

FIG. 2-3 is an explanatory sectional view of the manufacturing process of the solar cell according to the first embodiment of the present invention.

FIG. 2-4 is an explanatory sectional view of the manufacturing process of the solar cell according to the first embodiment of the present invention.

FIG. 2-5 is an explanatory sectional view of the manufacturing process of the solar cell according to the first embodiment of the present invention.

FIG. 2-6 is an explanatory sectional view of the manufacturing process of the solar cell according to the first embodiment of the present invention.

FIG. 2-7 is an explanatory sectional view of the manufacturing process of the solar cell according to the first embodiment of the present invention.

FIG. 2-8 is an explanatory sectional view of the manufacturing process of the solar cell according to the first embodiment of the present invention.

FIG. 2-9 is an explanatory sectional view of the manufacturing process of the solar cell according to the first embodiment of the present invention.

FIG. 3 is a flowchart for explaining the manufacturing process of the solar cell according to the first embodiment of the present invention.

FIG. 4 is a characteristic diagram illustrating a relation between the sectional area of a surface silver grid electrode and the fill factor (FF).

FIG. 5 is a characteristic diagram illustrating a relation between the width of a surface silver grid electrode and the fill factor (FF) in a solar cell in which the sectional area of the surface silver grid electrode is approximately 500 μm².

FIG. 6 is a characteristic diagram illustrating a relation between the sectional area of a surface silver grid electrode and the width of the surface silver grid electrode according to a difference in a forming method.

FIG. 7 is a characteristic diagram illustrating a relation between the number of surface silver bus electrodes and the short-circuit current density (Jsc) of a solar cell module.

FIG. 8 is a characteristic diagram illustrating a relation between the number of surface silver bus electrodes and the fill factor (FF) of a solar cell module.

FIG. 9 is a characteristic diagram illustrating a relation between the number of surface silver bus electrodes and the maximum output Pmax of a solar cell module.

FIG. 10 is a top view of a solar cell as viewed from a light-receiving surface side when the number of surface silver bus electrodes is four.

### DESCRIPTION OF EMBODIMENTS

Exemplary embodiments of a solar cell, a method for manufacturing the same, and a solar cell module according to the present invention will be explained below in detail with reference to the drawings. The present invention is not limited to the following descriptions, and can be modified as appropriate without departing from the scope of the present invention. In addition, in the drawings explained below, for ease of understanding, scales of respective members may be shown differently from what they actually are in reality. The same holds true for the relations between respective drawings.

### First Embodiment.

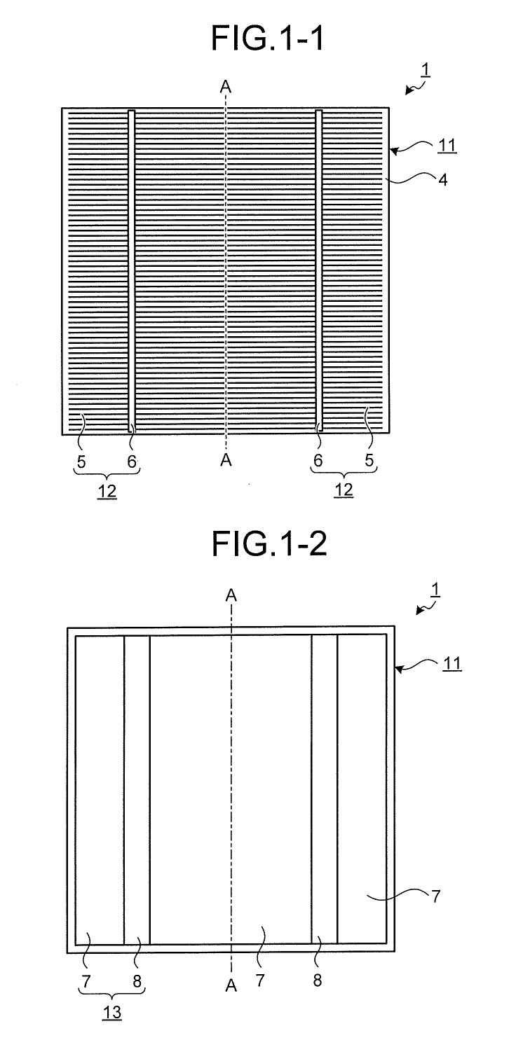

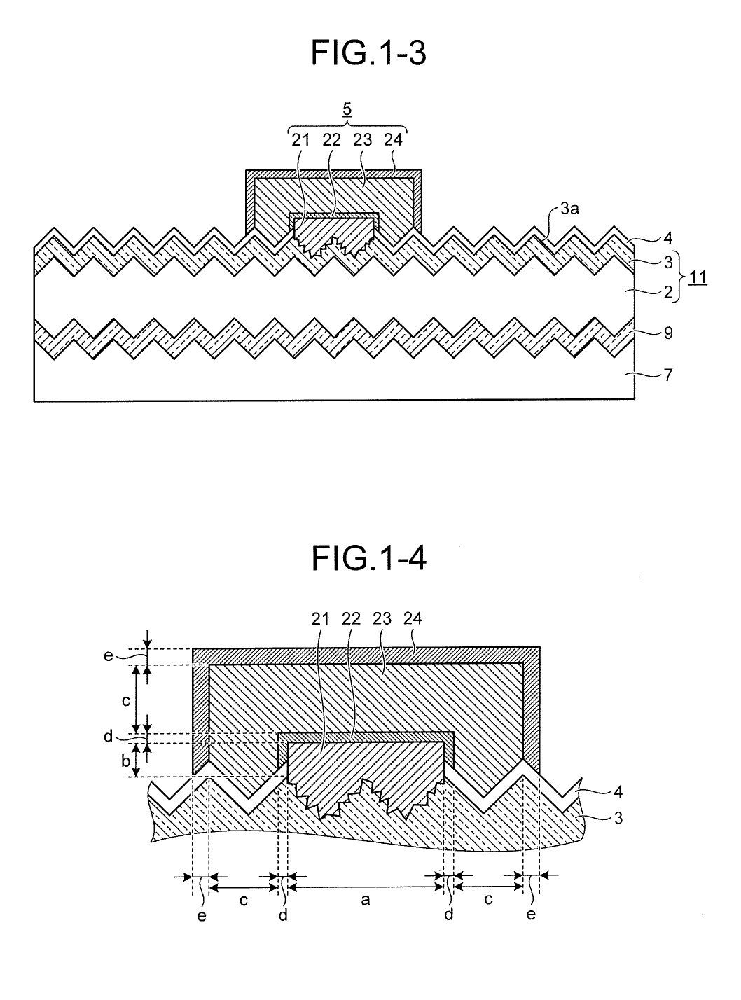

FIGS. 1-1 to 1-4 are explanatory diagrams of a configuration of a solar cell 1 according to a first embodiment of the present invention. FIG. 1-1 is a top view of the solar cell 1 as viewed from the light-receiving surface side. FIG. 1-2 is a bottom view of the solar cell 1 as viewed from the opposite side (the rear surface side) to the light-receiving surface. FIG. 1-3 is a sectional view of relevant parts of the solar cell 1. FIG. 1-3 is a sectional view of relevant parts in the direction of arrow A-A in FIG. 1-1. FIG. 1-4 is a sectional view of relevant parts in which the vicinity of a surface silver grid electrode of a light-receiving surface-side electrode in FIG. 1-3 is illustrated in an enlarged manner.

In the solar cell 1 according to the present embodiment, an n-type impurity diffusion layer 3 having a depth of about 0.3 micrometers to 0.5 micrometers is formed on the light-receiving surface side of a semiconductor substrate 2 formed of a p-type polycrystalline silicon by phosphorus diffusion, to form a semiconductor substrate 11 having a pn junction. An anti-reflective film 4 formed of a silicon nitride film (SiN film) is formed on the n-type impurity diffusion layer 3. The semiconductor substrate 2 is not limited to a p-type polycrystalline silicon substrate, and a p-type single-crystal silicon substrate, an n-type polycrystalline silicon substrate, or an n-type single-crystal silicon substrate can be used.

Microasperities 3a as a texture structure are formed on the surface on the light-receiving surface side of the semiconductor substrate 11 (the n-type impurity diffusion layer 3). The microasperities 3a have a structure that increases the area that absorbs light from the outside on the light-receiving surface and suppresses the reflectance on the light-receiving surface to confine the light.

The anti-reflective film 4 is formed of, for example, a silicon nitride film (SiN film) and is formed with a film thickness of, for example, about 70 nanometers to 90 nanometers on the surface on the light-receiving surface side (the light-receiving surface) of the semiconductor substrate 11 to prevent reflection of incident light on the light-receiving surface.

A plurality of long and thin surface silver grid electrodes 5 are provided side by side on the light-receiving surface side of the semiconductor substrate 11. Surface silver bus electrodes 6 in electrical communication with the surface silver grid electrodes 5 are provided substantially orthogonal to the surface silver grid electrodes 5, and the surface silver grid electrodes 5 and the surface silver bus electrodes 6 are electrically connected to the n-type impurity diffusion layer 3 on the bottom surfaces thereof. The surface silver grid electrodes 5 and the surface silver bus electrodes 6 are made of a silver material. A light-receiving surface-side electrode 12, which is a first electrode, is formed of the surface silver grid electrodes 5 and the surface silver bus electrodes 6. The light-receiving surface-side electrode 12 provided on the light-receiving surface side is formed in a comb-like shape to collect a generated electric current efficiently. Several tens of the surface silver grid electrodes 5 are formed such that they have a width of, for example, less than 60 micrometers. Meanwhile, the surface silver bus electrode 6 has a function of connecting the surface silver grid electrodes 5 with each other and has a width of, for example, 1 millimeters to 2 millimeters. There are two to four surface silver bus electrode 6.

The surface silver grid electrode 5 of the light-receiving surface-side electrode 12 includes a silver (Ag) paste electrode layer 21, which is a metal paste electrode and is directly bonded to the surface on the light-receiving surface side of the semiconductor substrate 11 (the n-type impurity diffusion layer 3), a nickel (Ni) plating electrode layer 22 formed by plating such that it covers the silver (Ag) paste electrode layer 21, a copper (Cu) plating electrode layer 23 formed by plating such that it covers the nickel (Ni) plating electrode layer 22, and a tin (Sn) plating electrode layer 24 formed by plating such that it covers the copper (Cu) plating electrode layer 23. The surface silver bus electrode 6 of the light-receiving surface-side electrode 12 has the same configuration as the surface silver grid electrode 5.

Meanwhile, a rear aluminum electrode 7 made of an aluminum material is provided over the entire rear surface of the semiconductor substrate 11 (the surface opposite to the light-receiving surface), and bar-like rear silver electrodes 8 made of a silver material are provided as extraction electrodes to extend substantially in the same direction as the surface silver bus electrodes 6. A rear-surface side electrode 13, which is a second electrode, is formed of the rear aluminum electrode 7 and the rear silver electrodes 8. The shape of the rear silver electrodes 8 can be a dot-like shape or the like.

An alloy layer (not illustrated) of aluminum (Al) and silicon (Si) is formed by firing the lower part of the rear aluminum electrode 7, which is a surface layer of the semiconductor substrate 11 on the rear surface side (the surface opposite to the light-receiving surface), and a p+ layer (BSF (Back Surface Field)) 9 containing high-concentration impurities by aluminum diffusion is formed under the alloy layer. The p+ layer (BSF) 9 is provided to obtain the BSF effect, and contributes to improvement of the energy conversion efficiency of the solar cell 1 by increasing the electron concentration in the p-type layer (the semiconductor substrate 2) by an electric field having a band structure so that electrons in the p-type layer (the semiconductor substrate 2) do not disappear.

In the solar cell 1 configured in this manner, when the pn-junction surface of the semiconductor substrate 11 (the junction surface between the semiconductor substrate 2 and the n-type impurity diffusion layer 3) is irradiated with sunlight from the light-receiving surface side of the solar cell 1, holes and electrons are generated. The generated electrons move toward the n-type impurity diffusion layer 3 and the holes move toward the p+ layer 9 by the electric field at the pn-junction portion. Accordingly, there are excess electrons in the n-type impurity diffusion layer 3, and there are excess holes in the p+ layer 9, thereby generating photovoltaic power. The photovoltaic power is generated in a direction in which the pn-junction is forward biased. Accordingly, the light-receiving surface-side electrode 12 connected to the n-type impurity diffusion layer 3 becomes a negative electrode, and the rear-surface side electrode 13 connected to the p+ layer 9 becomes a positive electrode; therefore, an electric current flows to an external circuit (not illustrated).

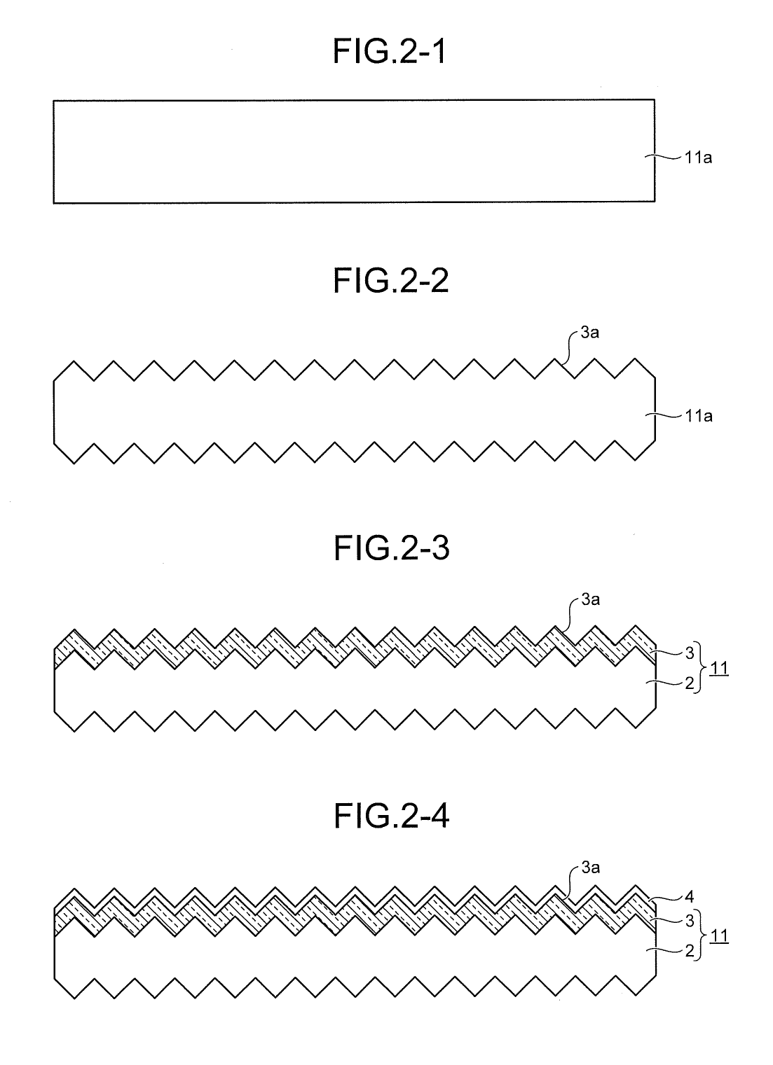

An example of a manufacturing method of the solar cell 1 according to the first embodiment is described next with reference to FIGS. 2-1 to 2-9. FIGS. 2-1 to 2-9 are explanatory sectional views of a manufacturing process of the solar cell 1 according to the first embodiment. FIG. 3 is a flowchart for explaining a manufacturing process of the solar cell 1 according to the first embodiment.

First, for example, a p-type polycrystalline silicon substrate most frequently used for consumer solar cells (hereinafter, “p-type polycrystalline silicon substrate 11a”) is prepared as a semiconductor substrate. Because the p-type polycrystalline silicon substrate 11a is manufactured by slicing, with a wire saw, an ingot formed by cooling and solidifying molten silicon, damage caused by slicing remains on the surface. Therefore, the p-type polycrystalline silicon substrate 11a is immersed in acid or a heated alkaline solution, for example, in aqueous sodium hydroxide solution to etch the surface thereof by a thickness of about, for example, 10 micrometers, thereby removing the damaged area that is generated when the silicon substrate is sliced and is present near the surface of the p-type polycrystalline silicon substrate 11a. (Step S10, FIG. 2-1).

Furthermore, simultaneously with damage removal, or subsequently thereto, the p-type polycrystalline silicon substrate 11a is immersed in an alkaline solution to perform anisotropic etching such that a silicon (111) surface is exposed, thereby forming the microasperities 3a of about 10 micrometers on the surface on the light-receiving surface side of the p-type polycrystalline silicon substrate 11a as a texture structure (Step S20, FIG. 2-2). By providing such a texture structure on the light-receiving surface side of the p-type polycrystalline silicon substrate 11a, multiple reflection of light is caused on the front surface side of the solar cell 1, and light entering the solar cell 1 can be efficiently absorbed into the semiconductor substrate 11, thereby enabling the reflectance to be effectively reduced and the conversion efficiency to be improved. When removal of the damaged layer and formation of the texture structure are performed in an alkaline solution, continuous processing is performed in some cases by adjusting the concentration of the alkaline solution according to individual purposes.

Because the present invention is related to electrode formation, the formation method and the shape of the texture structure are not particularly limited. Any method can be used, for example, a method of using an alkaline aqueous solution containing isopropyl alcohol or acid etching mainly using a mixed solution of hydrofluoric acid and nitric acid, a method of obtaining a honeycomb structure or an inverted pyramid structure on the surface of the p-type polycrystalline silicon substrate 11a by forming a mask material partially provided with an opening on the surface of the p-type polycrystalline silicon substrate 11a and performing etching via the mask material, or a method of using reactive gas etching (RIE: Reactive Ion Etching).

Next, the p-type polycrystalline silicon substrate 11a is put into a thermal oxidation furnace and is heated, for example, under an atmosphere of phosphorus (P), which is an n-type impurity. According to this process, phosphorus (P) is thermally diffused in the surface of the p-type polycrystalline silicon substrate 11a, to form the n-type impurity diffusion layer 3 with the conductivity type being inverted from that of the p-type polycrystalline silicon substrate 11a, thereby forming a semiconductor pn-junction. With this process, the semiconductor substrate 11 formed with the pn-junction is obtained by the semiconductor substrate 2 formed of the p-type polycrystalline silicon, which is a first-conductivity-type layer, and the n-type impurity diffusion layer 3, which is a second-conductivity-type layer and is formed on the light-receiving surface side of the semiconductor substrate 2 (Step S30, FIG. 2-3).

When there is no particular variation, the n-type impurity diffusion layer 3 is formed over the entire surface of the p-type polycrystalline silicon substrate 11a. The sheet resistance of the n-type impurity diffusion layer 3 is about, for example, several tens of Ω/□, and the depth of the n-type impurity diffusion layer 3 is, for example, about 0.3 micrometers to 0.5 micrometers.

Because a glassy (PSG: Phospho-Silicate Glass) layer deposited on the surface during a diffusion process is formed on the surface of the n-type impurity diffusion layer 3 immediately after formation of the n-type impurity diffusion layer 3, the phosphorus glass layer is removed by using a hydrofluoric acid solution or the like.

Although illustrations are omitted in the drawings, the n-type impurity diffusion layer 3 is formed over the entire surface of the p-type polycrystalline silicon substrate 11a. Therefore, in order to eliminate influences of the n-type impurity diffusion layer 3 formed on the rear surface and the like of the p-type polycrystalline silicon substrate 11a, the n-type impurity diffusion layer 3 is left only on one surface, which is to be the light-receiving surface side of the p-type polycrystalline silicon substrate 11a, and the n-type impurity diffusion layer 3 in the other area is removed by using, for example, a fluonitric acid solution in which hydrofluoric acid and nitric acid are mixed.

Next, a silicon nitride film (SiN film) having a film thickness of, for example, about 70 nanometers to 90 nanometers is formed as the anti-reflective film 4 over the entire surface on the light-receiving surface side of the p-type polycrystalline silicon substrate 11a (the semiconductor substrate 11) on which the n-type impurity diffusion layer 3 is formed in order to improve the photoelectric conversion efficiency (Step S40, FIG. 2-4). For example, a plasma CVD method is used for forming the anti-reflective film 4, and the silicon nitride film is formed as the anti-reflective film 4 by using a mixed gas of silane and ammonia.

An electrode is then formed. First, an aluminum paste 7a, which is an electrode material paste containing aluminum, is applied to the rear surface side of the semiconductor substrate 11 by screen printing in the shape of the rear aluminum electrode 7, a silver (Ag) paste (not illustrated), which is an electrode material paste containing silver, is applied to the rear surface side of the semiconductor substrate 11 by screen printing in the shape of the rear silver electrode 8, and then the pastes are dried (Step S50, FIG. 2-5).

Next, a silver (Ag) paste 21a, which is an electrode material paste containing silver, is applied to the light-receiving surface side of the semiconductor substrate 11 by gravure printing and dried (Step S60, FIG. 2-5). Only the silver paste portion for forming the surface silver grid electrode 5 of the silver paste 21a is illustrated in FIG. 2-5. In this example, only one layer of the silver paste 21a is applied by gravure printing. That is, the silver paste 21a is applied by gravure printing having an excellent thinning property to minimize the use of silver (Ag) as much as possible. Accordingly, an application shape of the silver paste 21a is a smaller in width and height than those of the final electrode shape.

Next, electrode pastes on the light-receiving surface side and the rear surface side of the semiconductor substrate 11 are simultaneously fired according to a firing profile for several minutes to several tens of minutes during which the peak temperature, for example, for several seconds becomes 700° C. to 900° C. (Step S70, FIG. 2-6). As a result, the aluminum paste 7a and the silver paste are fired on the rear surface side of the semiconductor substrate 11 to form the rear aluminum electrode 7 and the rear silver electrodes 8. Aluminum is also diffused as an impurity from the aluminum paste 7a to the rear surface side of the semiconductor substrate 11 during firing, and the p+ layer 9 containing aluminum as the impurity at a higher concentration than the semiconductor substrate 2 is formed immediately beneath the rear aluminum electrode 7.

Meanwhile, on the front surface side of the semiconductor substrate 11, the silver paste 21a melts the anti-reflective film 4 and penetrates therethrough during firing, and becomes the silver paste electrode layer 21 that can electrically come into contact with the n-type impurity diffusion layer 3. Such a process is referred to as “fire through method”. A thick film paste composition obtained by dispersing metallic powder as a main component and glass powder in an organic vehicle is used as the metal paste used as the electrode. The glass powder contained in the metal paste reacts with the silicon surface (the surface on the light-receiving surface side of the semiconductor substrate 11) and is firmly fixed thereto, thereby maintaining electric contact and mechanical adhesive strength between the n-type impurity diffusion layer 3 and the surface silver grid electrode.

In this case, a portion of the surface silver grid electrode 5 corresponding to the silver paste electrode layer 21 formed here is formed narrower in width and lower in height than the surface silver grid electrode formed only by the conventional screen printing. For example, the lower limit of the width of the surface silver grid electrode (the lower limit of thinning) by screen printing is about 50 micrometers and the lower limit of the height thereof is a maximum of 20 micrometers in a general surface electrode paste. In the screen printing, there is a tendency in which a trace of metal mesh is left and irregularities are repeated in the lengthwise direction at a regular interval, and in this case, the irregularities represent the height of a convex portion. On the other hand, in the first embodiment, because gravure printing is used, the portion of the surface silver grid electrode 5 corresponding to the silver paste electrode layer 21 is formed, for example, in a width of 20 micrometers and a height of 5 micrometers.

Next, Ni plating is performed on the silver paste electrode layer 21 by a plating method. With this process, the nickel (Ni) plating electrode layer 22 is formed such that it covers the silver paste electrode layer 21 (Step S80, FIG. 2-7). Cu plating is then performed on the nickel (Ni) plating electrode layer 22 by the plating method. With this process, the copper (Cu) plating electrode layer 23 is formed such that it covers the nickel (Ni) plating electrode layer 22 (Step S90, FIG. 2-8). Sn plating is then performed on the copper (Cu) plating electrode layer 23 by the plating method. With this process, the tin (Sn) plating electrode layer 24 is formed such that it covers the copper (Cu) plating electrode layer 23, thereby forming the light-receiving surface-side electrode 12, that is, the surface silver grid electrodes 5 and the surface silver bus electrodes 6 (Step S100, FIG. 2-9).

The copper (Cu) plating electrode layer 23 is an alternative electrode to a silver paste electrode. The copper (Cu) plating electrode layer 23 is formed, for example, with a film thickness of 5 micrometers to 20 micrometers. The nickel (Ni) plating electrode layer 22 is made of a metal material different from that of the silver paste electrode layer 21 and that of the copper (Cu) plating electrode layer 23. The nickel (Ni) plating electrode layer 22 enhances the bonding strength between the silver paste electrode layer 21 and the copper (Cu) plating electrode layer 23, renders the silver paste electrode layer 21 and the copper (Cu) plating electrode layer 23 conductive, and functions as a protection film for preventing diffusion of Cu or the like. The tin (Sn) plating electrode layer 24 is made of a metal material different from that of the copper (Cu) plating electrode layer 23, and functions as a protection film for protecting the copper (Cu) plating electrode layer 23. The nickel (Ni) plating electrode layer 22 and the tin (Sn) plating electrode layer 24 are formed with a thickness of 2 micrometers to 3 micrometers.

Plating is formed isotropically on the silver paste electrode layer 21 or a metallic layer in a lower layer. Therefore, as illustrated in FIG. 1-4, the width of the copper (Cu) plating electrode layer 23 formed on the side surface side of the silver paste electrode layer 21 in the planer direction of the semiconductor substrate 11 and the thickness of the copper (Cu) plating electrode layer 23 on the silver paste electrode layer 21 are the same, and expressed as a width (a film thickness) c of the copper (Cu) plating electrode layer 23. When a width a of the silver paste electrode layer and a thickness b of the silver paste electrode layer are used, the width of the surface silver grid electrode 5 becomes approximately a+c×2 and the thickness of the surface silver grid electrode 5 becomes b+c. It is assumed that the thickness b of the silver paste electrode layer is the thickness between the top portion in the height direction of the texture relief portion in the bottom portion of the silver paste electrode layer 21 and the upper surface of the silver paste electrode layer 21 formed after firing.

Furthermore, the width of the nickel (Ni) plating electrode layer 22 formed on the side surface of the silver paste electrode layer 21 in the planar direction of the semiconductor substrate 11 and the thickness (the film thickness) of the nickel (Ni) plating electrode layer 22 on the silver paste electrode layer 21 are the same, and are expressed as a width (the film thickness) d of the nickel (Ni) plating electrode layer 22. Further, the width of the tin (Sn) plating electrode layer 24 formed on the side surface of the copper (Cu) plating electrode layer 23 in the planar direction of the semiconductor substrate 11 and the thickness (the film thickness) of the tin (Sn) plating electrode layer 24 on the copper (Cu) plating electrode layer 23 are the same, and are expressed as a width (the film thickness) e of the tin (Sn) plating electrode layer 24. In this case, a precise width of the surface silver grid electrode 5 becomes a+d×2+c×2+e×2 and a precise thickness of the surface silver grid electrode 5 becomes b+d+c+e.

In this case, it is preferable to set the volume of the copper (Cu) plating electrode layer 23 to be, for example, equal to or more than three times the volume of the silver paste electrode layer 21. By setting the volume of the copper (Cu) plating electrode layer 23 to be, for example, equal to or more than three times the volume of the silver paste electrode layer 21, even if the volume (the sectional area) of the silver paste electrode layer 21 is small, the sectional area required for suppressing a reduction of the fill factor (FF) (a reduction of the photoelectric conversion efficiency) is ensured, and conductivity can be easily ensured.

Although it is away from the spirit of the first embodiment and not illustrated in the drawings, when plating processing is performed on the silver paste electrode layer 21, a laminated film in which an Ni plating film, a Cu plating film, and an Sn plating film having the same thickness are laminated in this order is formed also on the surface of the rear silver electrode 8, which is formed on the rear surface in order to constitute a solar cell module by connecting the solar cells 1 with each other in series.

By performing the processes described above, the solar cell 1 according to the first embodiment illustrated in FIG. 1-1 to FIG. 1-4 is completed.

A technique used as a method of thinning the surface silver grid electrodes 5 in the first embodiment is described here. Conventionally, methods of thinning the surface silver grid electrode have been carried out by using a silver paste, and one of the methods is offset printing (also referred to as the “gravure printing” described above or as “intaglio printing”). In the offset printing, the surface silver grid electrode having a width of less than 50 micrometers can be realized by using the silver paste. However, in the offset printing, in principle of printing, it is difficult to increase the thickness and efforts to increase the thickness have been made. For example, a technology is disclosed in Japanese Patent Application Laid-open No. 2011-178006 in which the thickness is increased by multiple printing in the offset printing. However, in practice, such multiple printing is difficult to perform in view of providing equipment, and thus mass production has not been realized.

Next, a design concept as an electrode for realizing cost reduction and high photoelectric conversion efficiency of the solar cell 1 according to the first embodiment is described. The copper (Cu) plating film in the present embodiment is an alternative to the silver (Ag) paste electrode. The electrical resistivity of the silver paste electrode is 1.62 μΩcm (20° C.), and the electrical resistivity of the copper (Cu) plating film is 1.69 μΩcm (20° C.). In other words, the both elements have approximately the same electrical resistivity. Therefore, the width of the surface silver grid electrodes 5 and design of the sectional area when the copper (Cu) plating film is used are the same as those when the silver paste electrode is used. Accordingly, the relation of the width and the sectional area of the surface silver grid electrode derived by using the silver (Ag) paste electrode can be directly applied to the method of thinning the surface silver grid electrodes 5 in the first embodiment.

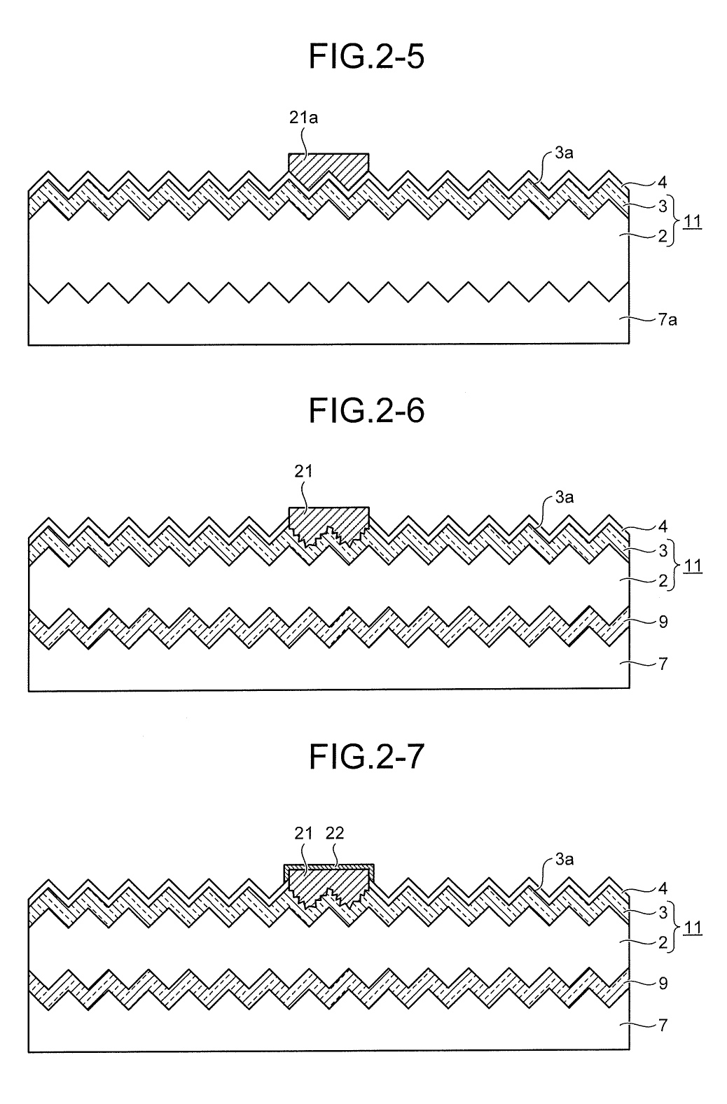

FIG. 4 is a characteristic diagram illustrating a relation between the sectional area of a surface silver grid electrode and the fill factor (FF). That is, FIG. 4 illustrates a dependency of the fill factor (FF) on the sectional area of the surface silver grid electrode. In this case, the sectional area of the surface silver grid electrode is changed by changing the width and height of the surface silver grid electrode to produce a plurality of solar cells, and the fill factor (FF) of the respective solar cells is measured. The surface silver grid electrode is a surface silver grid electrode (a silver paste electrode) formed by applying the silver paste by screen printing. In the respective solar cells, the conditions other than the sectional area of the surface silver grid electrode are set to be the same.

As can be understood from FIG. 4, as the sectional area of the surface silver grid electrode is reduced, the fill factor (FF) decreases. This is because, when the sectional area of the surface silver grid electrode is reduced, the electrical resistivity of the surface silver grid electrode increases. According to the result obtained by studying FIG. 4, it is understood that, if the sectional area of the surface silver grid electrode is reduced from 500 μm² to 300 μm² or less and up to 250 μm², the fill factor (FF) decreases by 0.01 or more, and in a relative ratio, a decrease of 1% or more occurs. If the sectional area of the surface silver grid electrode is reduced up to 200 μm² or less, the fill factor (FF) decreases further by 0.01 or more. Therefore, in view of practicality, the sectional area of the surface silver grid electrode is preferably 300 μm² or more, and more preferably, 500 μm² or more.

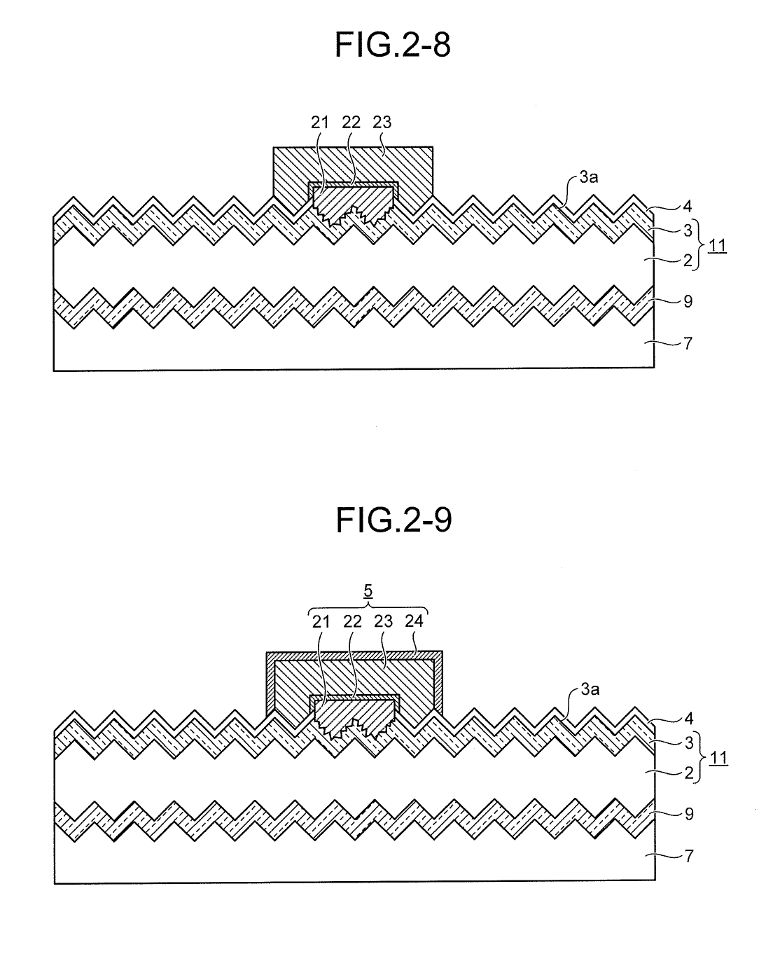

FIG. 5 is a characteristic diagram illustrating a relation between the width of a surface silver grid electrode and the fill factor (FF) in a solar cell in which the sectional area of the surface silver grid electrode is approximately 500 μm². That is, FIG. 5 illustrates a dependency of the fill factor (FF) on the width of the surface silver grid electrode. In this case, a plurality of solar cells are produced by changing the width and height of the surface silver grid electrode with the sectional area of the surface silver grid electrode being kept at approximately 500 μm², and the fill factor (FF) of the respective solar cells is measured. The surface silver grid electrode is a surface silver grid electrode (a silver paste electrode) formed by applying the silver paste by screen printing. In the respective solar cells, the conditions other than the width and height of the surface silver grid electrode are set to be the same.

As can be understood from FIG. 5, as the width of the surface silver grid electrode is reduced, the fill factor (FF) decreases. This is because, when the width of the surface silver grid electrode is reduced, the contact area between the surface silver grid electrode and the silicon substrate decreases. According to the result obtained by studying FIG. 5, it is understood that if the sectional area of the surface silver grid electrode is about 500 μm², the decrease of the fill factor (FF) in the case of thinning the width of the surface silver grid electrode from 100 micrometers to 50 micrometers is about 0.0075, and in a relative ratio, a decrease of less than 1% occurs.

When the number of surface silver grid electrodes is set to be the same, as the surface silver grid electrode is thinned, the light-receiving area increases to improve the short-circuit current density (Jsc); however, the fill factor (FF) decreases. The degree of decrease of the fill factor (FF) has the relation described above, and in order to achieve higher photoelectric conversion efficiency by thinning the surface silver grid electrode, the electrode width needs to be set while taking the sectional area of the surface silver grid electrode into consideration.

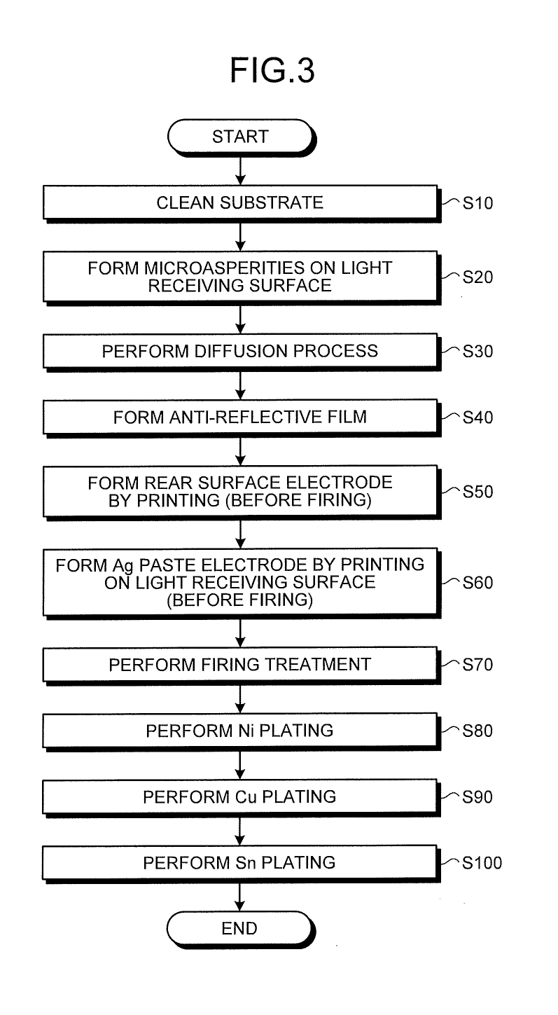

FIG. 6 is a characteristic diagram illustrating a relation between the sectional area of a surface silver grid electrode and the width of the surface silver grid electrode according to a difference in a forming method. In FIG. 6, a plurality of solar cells are produced for a case where a silver paste electrode to be the surface silver grid electrode is formed by screen printing (a comparative example 1), a case where a silver paste electrode to be the surface silver grid electrode is formed of only one layer by gravure printing (a comparative example 2), and a case where after a silver paste electrode to be the surface silver grid electrode is formed of one layer by gravure printing according to the method of the first embodiment, Ni/Cu/Sn plating films are formed thereon (Example), and a range within which the surface silver grid electrode can be thinned with respect to a predetermined sectional area of the surface silver grid electrode is checked. As for the Example, a case of using an electrode layer having a width of 20 micrometers and a thickness of 5 micrometers as the silver electrode (the silver paste electrode layer 21) is illustrated. In FIG. 6, the electrode width and the sectional area after plating are illustrated. As for the comparative example 2, the thickness of the silver paste electrode by gravure printing is 5 micrometers.

Gravure printing (the comparative example 2) has the highest potential for thinning the surface silver grid electrode. However, if the surface silver grid electrode is formed of one layer, the sectional area decreases. In order to increase the sectional area of the surface silver grid electrode with one layer, the width thereof needs to be increased. Therefore, for example, even if a smaller sectional area of about 300 μm² is considered, it is difficult to realize the electrode width of less than 60 micrometers. Further, in the case of screen printing (the comparative example 1), even if the sectional area is reduced, it is difficult to realize the final electrode width of 50 micrometers by using a silver paste of a specification of viscosity considering the current mass production.

In contrast, in the case of the method according to the first embodiment (Example) combining the gravure printing and plating, the sectional area of 300 μm² or more and up to about 750 μm² can be realized in the surface silver grid electrode having a width of less than 60 micrometers, more specifically, a width of less than about 50 micrometers. In this manner, in the solar cell 1 according to the first embodiment, both thinning of the electrode and ensuring of the sectional area of the electrode are realized, which have not been previously realized.

As described above, a silver paste electrode that is a base of a surface silver grid electrode is formed by gravure printing, with which thinning is possible but the sectional area cannot be increased in the case of formation of only one layer, and then copper (Cu), which is inexpensive compared to silver (Ag), is formed by plating on the silver paste electrode. Accordingly, it is possible to realize thinning further than other electrode forming techniques with a lower cost, while ensuring a sectional area required for suppressing a decrease of the fill factor (FF) (a decrease of the photoelectric conversion efficiency).

Even when a silver paste electrode is plated with silver, as illustrated in FIG. 6, the present method is more advantageous than using other electrode forming techniques alone. Therefore, from the viewpoint of achieving high photoelectric conversion efficiency, it is also possible to plate the silver paste electrode with silver by gravure printing.

Furthermore, in the surface silver grid electrode 5 formed by the method according to the first embodiment, glass powder contained in a metal paste (the silver paste 21a) reacts with the silicon surface (the surface on the light-receiving surface side of the semiconductor substrate 11) and is firmly fixed, thereby maintaining electric contact and mechanical bonding strength between the n-type impurity diffusion layer 3 and the surface silver grid electrode 5. Therefore, also with regard to the reliability, the surface silver grid electrode 5 formed by the method according to the first embodiment has properties that are the same as those of the silver paste electrode formed by screen printing.

The above is the theory regarding achievement of cost reduction and high photoelectric conversion efficiency (thinning) of a surface silver grid electrode in the method for manufacturing the solar cell according to the first embodiment. However, if thinning of the surface silver grid electrode is promoted, the contact area between the surface silver grid electrode and the silicon substrate decreases, and then the fill factor (FF) decreases as illustrated in FIG. 5. Therefore, a method of compensating the decrease of the fill factor (FF) due to the thinning of the surface silver grid electrode is examined. Here, the number of surface silver bus electrodes of the light-receiving surface-side electrode is increased in order to improve the fill factor (FF), and the dependency on the number of surface silver bus electrodes in the solar cell is examined.

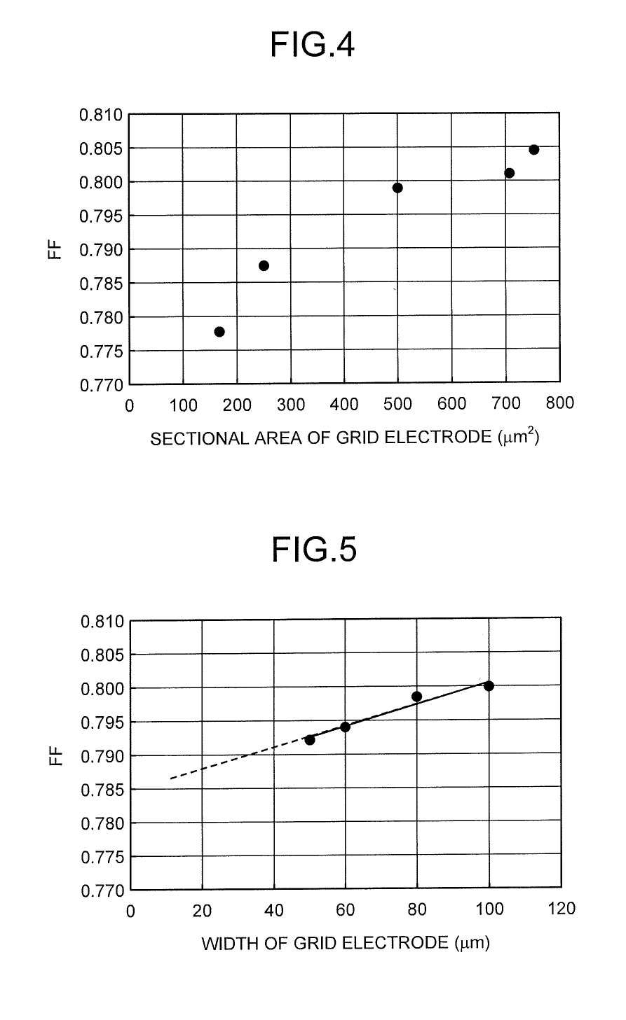

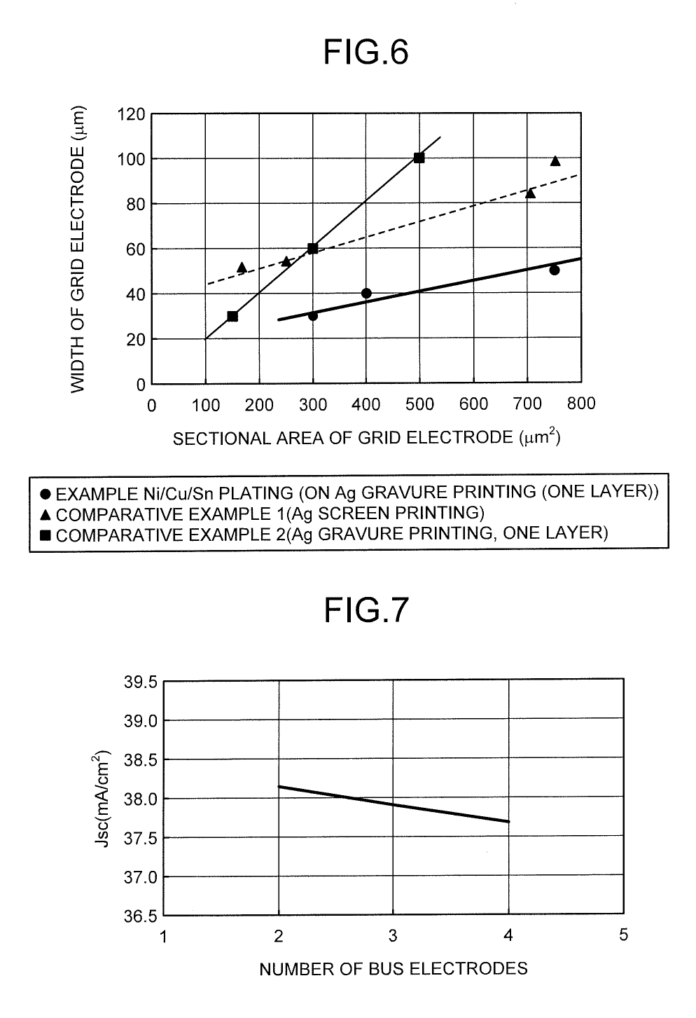

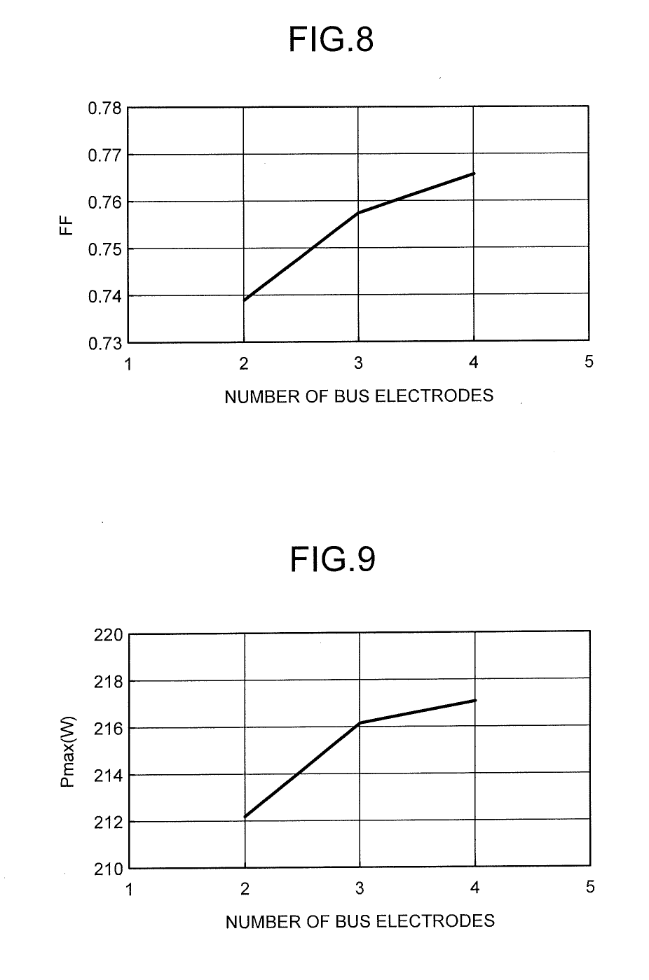

FIG. 7 is a characteristic diagram illustrating a relation between the number of surface silver bus electrodes and the short-circuit current density (Jsc) of a solar cell module. FIG. 8 is a characteristic diagram illustrating a relation between the number of surface silver bus electrodes and the fill factor (FF) of a solar cell module. FIG. 9 is a characteristic diagram illustrating a relation between the number of surface silver bus electrodes and the maximum output Pmax (W) of a solar cell module. The solar cell module is configured by connecting in series 50 solar cells produced by the method for manufacturing the solar cell according to the first embodiment by using a p-type single-crystal silicon substrate of 156 square millimeters. The surface silver bus electrode has a single width of 1.5 millimeters. The number of surface silver bus electrodes is two, three, and four.

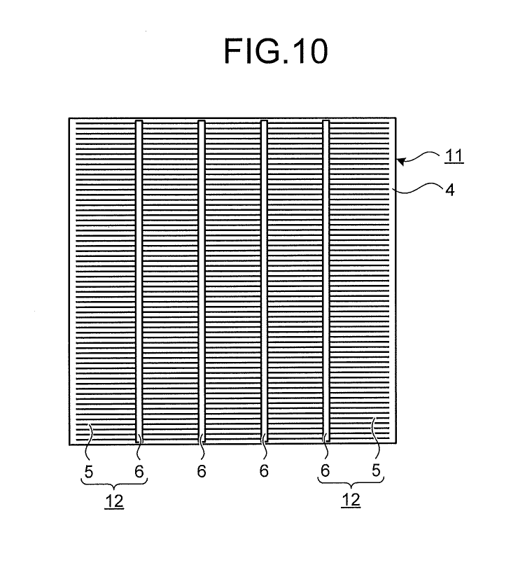

As illustrated in FIG. 7, the short-circuit current density (Jsc) monotonically decreases with an increase of the number of surface silver bus electrodes. Meanwhile, as illustrated in FIG. 8, the fill factor (FF) increases with the increase of the number of surface silver bus electrodes. When the open voltage does not change, the maximum output Pmax corresponds to the relation of the product of the short-circuit current density (Jsc) and the fill factor (FF). In the present example, as illustrated in FIG. 9, it is found that the highest output can be obtained in the case of the number of surface silver bus electrodes being four. FIG. 10 is a top view of the solar cell as viewed from the light-receiving surface side when the number of surface silver bus electrodes is four.

The width of the surface silver bus electrode is preferably 1.5 millimeters or less. If the width of the surface silver bus electrode is wider than 1.5 millimeters, the electric resistance of the surface silver bus electrode decreases and power collection from the grid electrode becomes easy; however, the degree of decrease of the light-receiving area increases. Furthermore, it is required that the mechanical strength of the tab electrodes to be formed by soldering on the bus electrode in the case of interconnection thereof is such an extent that the tab electrodes do not peel off due to handling or the like during the assembly process. In order to maintain this mechanical strength, the lower limit of the width of the surface silver bus electrode is about 0.5 millimeters.

In the above descriptions, an electrode structure that achieves cost reduction (alternative material: use of Cu) and high photoelectric conversion efficiency (thinning) of the light-receiving surface-side electrode 12 at the same time has been described. Eventually, it can be said that it is necessary to also regard the number of surface silver bus electrodes as a subject to be studied. Therefore, in the first embodiment, in order to realize thinning of the surface silver bus electrode so that the width thereof becomes less than 50 micrometers and the cost reduction thereof, it is most effective to form the silver paste electrode with a width of, for example, 20 micrometers by gravure printing, and then perform plating of Cu or the like. To maximize the effect thereof, it has been described that, preferably, the number of surface silver bus electrodes having an electrode width of 1.5 millimeters or less is increased, and, as the number of surface silver bus electrodes, three is better than two and four is most preferable.

As described above, in the first embodiment, a silver paste electrode that is a base of a surface silver grid electrode is formed by gravure printing, and copper (Cu) and tin (Sn), which are inexpensive compared to nickel (Ni) and silver (Ag), are plated on the silver paste electrode. Accordingly, it is possible to realize thinning further than other electrode forming techniques such as screen printing, while ensuring a sectional area required for suppression of a decrease of the fill factor (FF) (a decrease of the photoelectric conversion efficiency) and thus ensuring conductivity of electrodes.

Furthermore, in the first embodiment, a copper (Cu) plating film that is an inexpensive metal material is used as an alternative material to silver (Ag), which is an expensive constituent material, thereby enabling cost reduction of solar cells.

Further, in the first embodiment, in the surface silver grid electrode 5, glass powder contained in a metal paste (the silver paste 21a) reacts with the silicon surface (the surface on the light-receiving surface side of the semiconductor substrate 11) and is firmly fixed, thereby ensuring electric contact and mechanical bonding strength between the n-type impurity diffusion layer 3 and the surface silver grid electrode 5. Therefore, also with regard to the reliability, the surface silver grid electrode 5 has properties that are the same as those of the silver paste electrode formed by screen printing.

While surface silver grid electrodes have been described above, similar effects can be obtained for surface silver bus electrodes.

Therefore, according to the first embodiment, a solar cell that realizes cost reduction, high photoelectric conversion efficiency, and high reliability can be obtained.

### Second Embodiment.

In a second embodiment, a case of using a dispenser is described. In the second embodiment, in the method described in the first embodiment, a dispenser is used instead of gravure printing to apply the silver paste 21a, thereby achieving thinning of the surface silver grid electrodes 5. In this case, basically, the printing width of the silver paste 21a is controlled by the diameter of the nozzle of the dispenser, thereby enabling the width of the surface silver grid electrodes 5 to be controlled. However, if the discharge rate for obtaining a required sectional area is increased by using a conventional silver paste, the silver paste spreads due to low viscosity of the silver paste; therefore, an electrode having a high aspect ratio cannot be formed.

Therefore, a silver paste having a UV curing function is described in, for example, Japanese Patent Application Laid-Open No. 2012-216827. In this Patent Literature, the inventors thereof have proposed that an electrode having a high aspect ratio from 1 to 3 can be formed by applying a silver paste having a UV curing function by a dispenser. However, the silver paste having a UV curing function has become expensive due to addition of the UV curing function, and is not widely used enough to be suitable for mass production, thereby becoming an even more expensive electrode material. In this way, the cost becomes expensive to obtain an electrode having a high aspect ratio only by a simple effect of the silver paste having a UV curing function.

However, in the method for manufacturing the solar cell described in the first embodiment, the silver paste electrode layer 21 only requires a thickness at the lowest level. When a general Ag paste that does not have a UV curing function is used for a dispenser, if the width of 20 micrometers is to be realized, the thickness becomes about 5 micrometers, and the shape becomes similar to the shape when one layer of the general Ag paste is formed by gravure printing. Therefore, in the method for manufacturing the solar cell described according to the first embodiment, as the silver paste 21a is applied by using a dispenser instead of gravure printing to form the silver paste electrode layer 21, it is possible to obtain effects similar to those of the first embodiment.

Furthermore, by forming a plurality of solar cells having the configuration described in the above embodiments and electrically connecting adjacent solar cells to each other in series or in parallel, a solar cell module having an excellent optical confinement effect, reliability, and photoelectric conversion efficiency can be realized. In this case, for example, it suffices that the light-receiving surface-side electrode 12 of one of the adjacent solar cells is electrically connected with the rear surface side electrode 13 of the other one of the solar cells.

### INDUSTRIAL APPLICABILITY

As described above, the solar cell according to the present invention is useful for realizing a solar cell that achieves cost reduction and high photoelectric conversion efficiency at the same time.

### REFERENCE SIGNS LIST

1 solar cell, 2 semiconductor substrate, 3 n-type impurity diffusion layer, 3a microasperities, 4 anti-reflective film, 5 surface silver grid electrode, 6 surface silver bus electrode, 7 rear aluminum electrode, 7a aluminum paste, 8 rear silver electrode, 9 p+ layer (BSF (Back Surface Field)), 11 semiconductor substrate, 11a p-type polycrystalline silicon substrate, 12 light-receiving surface-side electrode, 13 rear surface side electrode, 21 silver paste electrode layer, 21a silver paste, 22 nickel (Ni) plating electrode layer, 23 copper (Cu) plating electrode layer, 24 tin (Sn) plating electrode layer.

1. A solar cell comprising:
a first-conductivity-type semiconductor substrate that includes an impurity diffusion layer, in which a second-conductivity-type impurity element is diffused, on one surface side, which is a light-receiving surface side;
an anti-reflective film that is formed on the one surface side of the semiconductor substrate;
a light-receiving surface-side electrode that includes a grid electrode and a bus electrode having a wider width than the grid electrode and in electrical communication with the grid electrode, and that is formed on the one surface side so as to be electrically connected to the impurity diffusion layer; and
a rear surface side electrode that is formed on a rear surface opposite-opposed to the one surface side of the semiconductor substrate so as to be electrically connected to the impurity diffusion layer, wherein
the light-receiving surface-side electrode includes
a first metal electrode layer that is a metal paste electrode layer penetrating the anti-reflective film and directly bonded to the one surface side of the semiconductor substrate, and
a second metal electrode layer that is a plating electrode layer that is formed of a metal material different from the first metal electrode layer and having an electrical resistivity substantially equivalent to an electrical resistivity of the first metal electrode layer, that covers a top surface and a side surface of the first metal electrode layer, and that is formed, on a side surface side of the first metal electrode layer, on the anti-reflective film, and
a sectional area of the grid electrode is 300 μm² or more, and an electrode width of the grid electrode is 60 micrometers or less.

2. The solar cell according to claim 1, wherein
the first metal electrode layer is a silver paste electrode layer, and
the second metal electrode layer is a copper plating electrode layer.

3. The solar cell according to claim 2, wherein a volume of the second metal electrode layer is equal to or more than three times a volume of the first metal electrode layer.

4. The solar cell according to claim 1, further comprising:
a third metal electrode layer that is a plating electrode layer that is formed of a metal material different from the first metal electrode layer and the second metal electrode layer and enhancing a bonding strength between the first metal electrode layer and the second metal electrode layer, that is formed between the first metal electrode layer and the second metal electrode layer, and that is formed, on the side surface side of the first metal electrode layer, on the anti-reflective film; and
a fourth metal electrode layer that is a plating electrode layer that is formed of a metal material different from the second metal electrode layer and protecting the second metal electrode layer, that covers a top surface and a side surface of the second metal electrode layer, and that is formed, on a side surface side of the second metal electrode layer, on the anti-reflective film.

5. The solar cell according to claim 4, wherein
the third metal electrode layer is a nickel plating layer, and
the fourth metal electrode layer is a tin plating layer.

6. The solar cell according to claim 5, wherein
an electrode width of the bus electrode is 1.5 millimeters or less, and
number of the bus electrodes is three or more.

7. A method for manufacturing a solar cell, comprising:
forming an impurity diffusion layer on one surface side, which becomes a light-receiving surface side, of a first-conductivity-type semiconductor substrate by diffusing a second-conductivity-type impurity element in the one surface side of the semiconductor substrate;
forming an anti-reflective film on the one surface side of the semiconductor substrate;
forming a light-receiving surface-side electrode that is electrically connected to the impurity diffusion layer on the one surface side of the semiconductor substrate; and
forming a rear surface side electrode that is electrically connected to another surface side of the semiconductor substrate on the another surface side of the semiconductor substrate, wherein
the forming the light-receiving surface-side electrode includes
forming a first metal electrode layer by applying a metal paste to the anti-reflective film formed on the one surface side of the semiconductor substrate by offset printing or a dispenser and firing the metal paste, the first metal electrode layer being a metal paste electrode layer penetrating the anti-reflective film and directly bonded to the one surface side of the semiconductor substrate, and
forming a second metal electrode layer by plating such that the second metal electrode layer covers a top surface and a side surface of the first metal electrode layer and is formed, on a side surface side of the first metal electrode layer, on the anti-reflective film, the second metal electrode layer being a plating electrode layer that is formed of a metal material different from the first metal electrode layer and having an electrical resistivity substantially equivalent to an electrical resistivity of the first metal electrode layer.

8. The method for manufacturing a solar cell according to claim 7, wherein
the first metal electrode layer is a silver paste electrode layer, and
the second metal electrode layer is a copper plating electrode layer.

9. The method for manufacturing a solar cell according to claim 8, wherein a volume of the second metal electrode layer is equal to or more than three times a volume of the first metal electrode layer.

10. The method for manufacturing a solar cell according to claim 7, wherein
forming the light-receiving surface-side electrode includes
forming a third metal electrode layer by plating such that the third metal electrode layer is formed between the first metal electrode layer and the second metal electrode layer and is formed, on the side surface side of the first metal electrode layer, on the anti-reflective film, the third metal electrode layer being a plating electrode layer that is formed of a metal material different from the first metal electrode layer and the second metal electrode layer and enhancing a bonding strength between the first metal electrode layer and the second metal electrode layer, and
forming a fourth metal electrode layer by plating such that the fourth metal electrode layer covers a top surface and a side surface of the second metal electrode layer and is formed, on a side surface side of the second metal electrode layer, on the anti-reflective film, the fourth metal electrode layer being a plating electrode layer that is formed of a metal material different from the second metal electrode layer and protecting the second metal electrode layer.

11. The method for manufacturing a solar cell according to claim 10, wherein
the third metal electrode layer is a nickel plating layer, and
the fourth metal electrode layer is a tin plating layer.

12. The method for manufacturing a solar cell according to claim 11, wherein
the light-receiving surface-side electrode includes a grid electrode and a bus electrode having a wider width than the grid electrode and in electrical communication with the grid electrode, and
a sectional area of the grid electrode after formation of the first metal electrode layer, the second metal electrode layer, the third metal electrode layer, and the fourth metal electrode layer is 300 μm² or more, and an electrode width of the grid electrode is 60 micrometers or less.

13. The method for manufacturing a solar cell according to claim 12, wherein
an electrode width of the bus electrode after formation of the first metal electrode layer, the second metal electrode layer, the third metal electrode layer, and the fourth metal electrode layer is 1.5 millimeters or less, and
number of the bus electrodes is three or more.

14. (canceled)

15. A solar cell module, wherein two or more of the solar cells according to claim 1 are electrically connected in series or in parallel.
